(19) United States
(12) Patent Application Publication
(10) Pub. No.: US 2012/0227791 A1
(43) Pub. Date: Sep. 13, 2012

(54) Mounting, grounding and wire management systems for solar panel arrays

(76) Inventor: Peter Vari, Richboro, PA (US)

(21) Appl. No.: 13/135,942

(22) Filed: Jul. 19, 2011

Related U.S. Application Data
(63) Continuation-in-part of application No. 12/657,322, filed on Jan. 19, 2010.
(60) Provisional application No. 61/400,602, filed on Jul. 30, 2010.

(51) Int. Cl. H01L 31/048

(52) U.S. Cl. 136/251

(57) ABSTRACT

Systems for mounting and retaining solar panels are disclosed. In particular, systems for conventional tilted roofs (gable, hip, etc.) and for ground installations. Additionally, systems for electrically grounding the components of a solar panel assembly and systems for managing the many electrical wires that must be run along the installation to interconnect and ground the solar panels and supporting structures are disclosed.

This application is related to pending U.S. patent application Ser. No. 12/657,322, filed Jan. 19, 2010 entitled “FASTENER FREE ASSEMBLY FOR SOLAR PANEL ARRAYS” and pending U.S. Patent Application Ser. No. 61/400,602, filed Jul. 30, 2010 entitled “SOLAR RACKING SYSTEM both of which are incorporated in their entirety herein by reference.”

### BACKGROUND OF THE INVENTION

The present invention is directed to systems for mounting and retaining solar panels. In particular, the present invention preferably adapted to be used in two styles of photovoltaic (PV) solar panel installations. One is for conventional tilted roofs (gable, hip, etc.) and the second is ground installations. Additionally, the present invention is directed to systems for electrically grounding the components of a solar panel assembly and to systems for managing the many electrical wires that must be run along the installation to interconnect and ground the solar panels and supporting structures.

The prior art includes numerous styles of racking systems for roof installations, for example those made by Unirac, DPW, IronRidge and others. Most of these systems use clamps to hold modules in place and provide no wire management solutions. Clamp-free racking systems for ground installations are even less prevalent.

### SUMMARY OF THE INVENTION

The system of the present invention therefore provides a solution of a long-felt and as of yet unmet need. The system of the present invention is, in preferred embodiments, a system that includes grounding components and includes wire management. Installations using the system of the present invention are mechanically superior due to the fact that the modules are fully encapsulated (as opposed to the clamping methods used in the prior art, where a few clamps hold the modules in place at discrete points.) The system of the present invention significantly reduces or eliminates mechanical stresses that typically exist in prior art bolted/clamped racking systems due to temperature created expansion/contraction cycles. The system of the present invention eliminates the clamping bolt failures that typically occur in prior art bolted/clamped racking systems due to substandard installation techniques. In racking systems made in accordance with the present invention, solar panel modules are captivated but not restricted from expansion or contraction. An installation using the system of the present invention is also installed more quickly than other systems due to the fact that there are just a minimal number of fasteners, and the installation is simpler because easy adjustments are designed into the system.

### BRIEF DESCRIPTION OF DRAWINGS

FIG. 1 is a perspective view of a ground installation of a solar panel array;

FIG. 2 is a close up perspective view of a portion of the solar array depicted in FIG. 1;

FIG. 3 is an elevation view of a support member and stopper block made in accordance with certain aspects of the present invention;

FIG. 4 is a close up perspective view of a roof installation of a solar panel array;

FIG. 5 is a perspective view illustrating the support members of the array illustrated in FIG. 4;

FIG. 6 is an elevation view of a horizontal support member made in accordance with certain aspects of the present invention;

FIG. 7 is an elevation view of a vertical support member made in accordance with certain aspects of the present invention;

FIG. 8 is a side elevation view of two of the horizontal support members shown in FIG. 6 engaging a solar panel;

FIG. 9 is a plan view of a horizontal end cap;

FIG. 10 is a plan view of a vertical end cap;

FIG. 11 is a side elevation view of a preferred embodiment for grounding a horizontal support member that is connected to a vertical support member;

FIG. 12 is a top plan view of a section of a solar pane array illustrating a grounding system made in accordance with the present invention;

FIG. 13 is a perspective view of an alternate embodiment of a grounding system;

FIG. 14 is a perspective view of another alternate embodiment of a grounding system;

FIG. 15 is a perspective view of a grounding element;

FIG. 16 is an elevation view of the grounding element shown in FIG. 15 disposed between a solar panel frame and a support member;

FIGS. 17A-17B illustrate the installation the grounding element show in FIGS. 15-16;

FIG. 18 is a front view of a first embodiment of a wire management system made in accordance with the present invention;

FIG. 19 is a perspective view of the wire management system shown in FIG. 18;

FIG. 20 is an elevation view of a second embodiment of a wire management system made in accordance with the present invention;

FIG. 21 is an enlarged view of the system shown in FIG. 20 illustrating further details of the system; and

FIG. 22 illustrates an alternate embodiment of the wire management system shown in FIGS. 20-21;

### DETAILED DESCRIPTION OF THE PREFERRED EMBODIMENTS

Applicant's co-pending application is directed to a solar panel racking system, which in certain embodiments is preferably employed on flat, commercial roofs. The present invention is in general related to a solar panel racking system that is preferably adapted to be used in two styles of photovoltaic (PV) solar panel installations. One is conventional, tilted roofs (gable, hip, etc.) and the second is ground installations. Additionally, embodiments of the racking system of the present invention preferably have at least one of two novel subsystems disclosed herein. One is for electrically grounding the components and the other is managing the many wires that must be run along the racking.

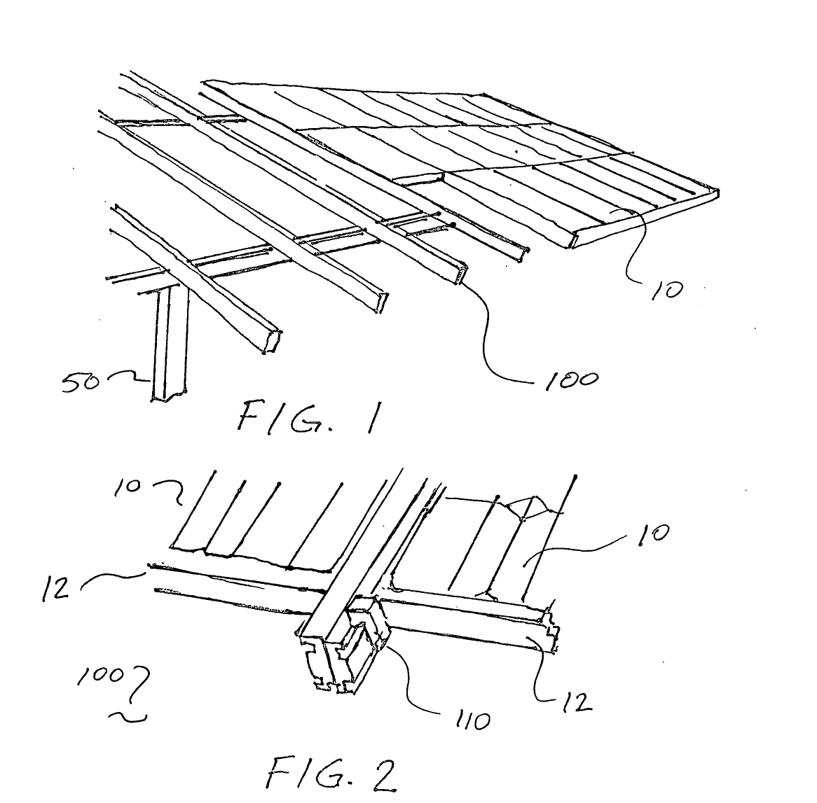

In a first embodiment, the present invention provides a racking system that has as a primary component a specialized support member and accessories. Referring now to FIG. 1, there is shown a perspective view of a ground installation of an array of solar panels 10 in accordance with certain aspects of the present invention. A plurality of solar panels 10 are mounted between support members 100, which as explained below preferably have a particular cross sectional profile adapted to retain the solar panels 10 in place. The support members 100 are typically but not necessarily attached to a substructure 50, which those of skill in the art will understand will vary depending upon the size of the installation, terrain, climate and other factors. The support member 100 is mounted to a substructure 50 in any conventional manner familiar to those of skill in the art. Each solar module 10 is captivated between two support members 100. Referring now to FIG. 2, it can be seen that a stopper plate 110 keeps the solar panel 10 in place. Also visible in this view is the solar module frame 12 that typically provides support and mounting points for the solar modules 10. Once the support members 100 are mounted on the substructure 50 at proper spacing the solar panels 100 are inserted into the support member 100. The dimensions of the solar module 10 dictate the spacing between support members 100.

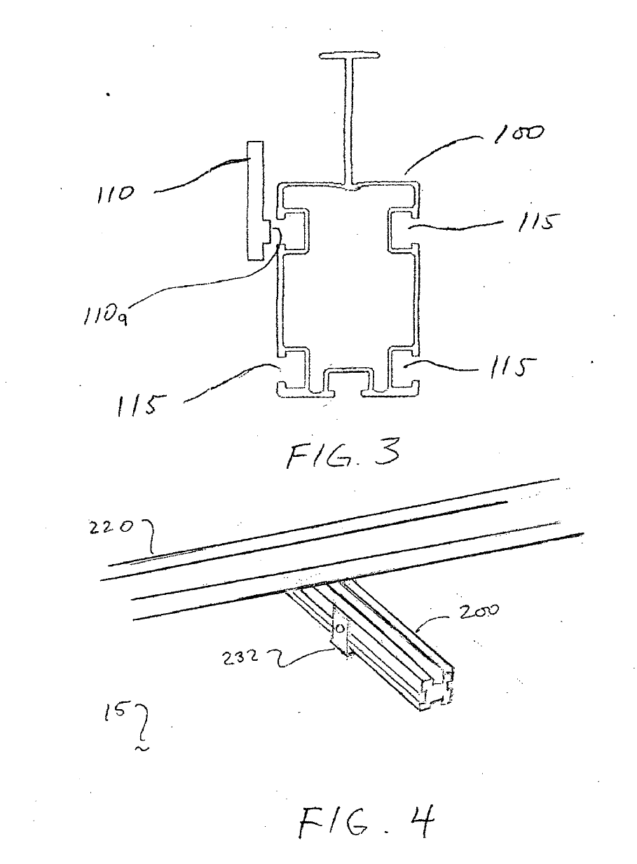

Referring now to FIG. 3 a close up elevation end view of one support member 100 is shown. The solar modules 10 (not shown in FIG. 3) are prevented from sliding out by the stopper plate 110, as seen in FIGS. 2-3. In preferred embodiments, two stopper plates 110 are disposed on opposite sides of the support member 100. The stopper plates incorporate a protrusion 110a, as seen in FIG. 3, that keys into the T-slot 115 preventing the stopper plate from rotating. FIG. 3 further illustrates the details of the cross-section of the support member 100, the details of which are explained below. It will be understood, however, that the present invention is not limited to the cross-section shown and numerous variations to the cross-section of the support member 100 are feasible. In cross-section, the support member 100 has slots 115 which are preferably “T-shaped” and accommodate the head of a bolt or other hardware, which can then be slid along the length of the support member 100 and fastened as desired, either for mechanical security, grounding, wire management, accessory mounting, or other reasons.

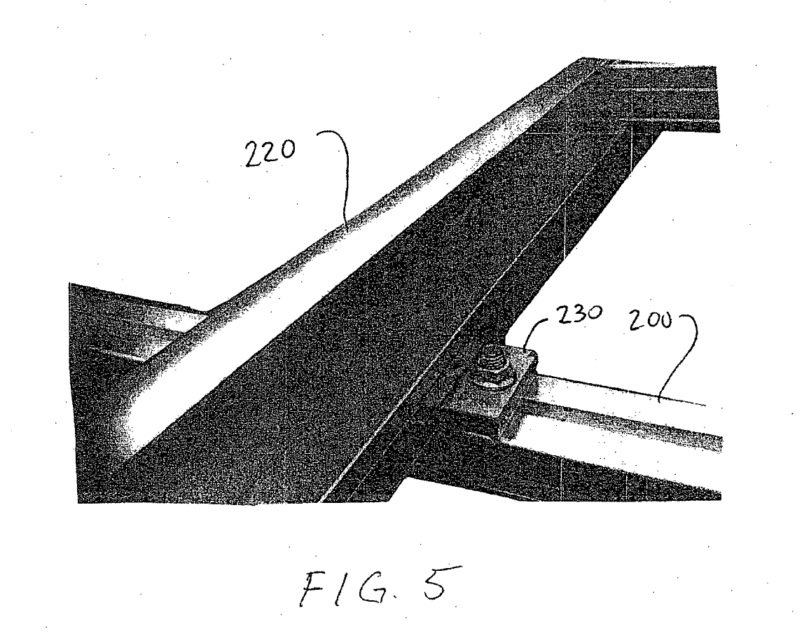

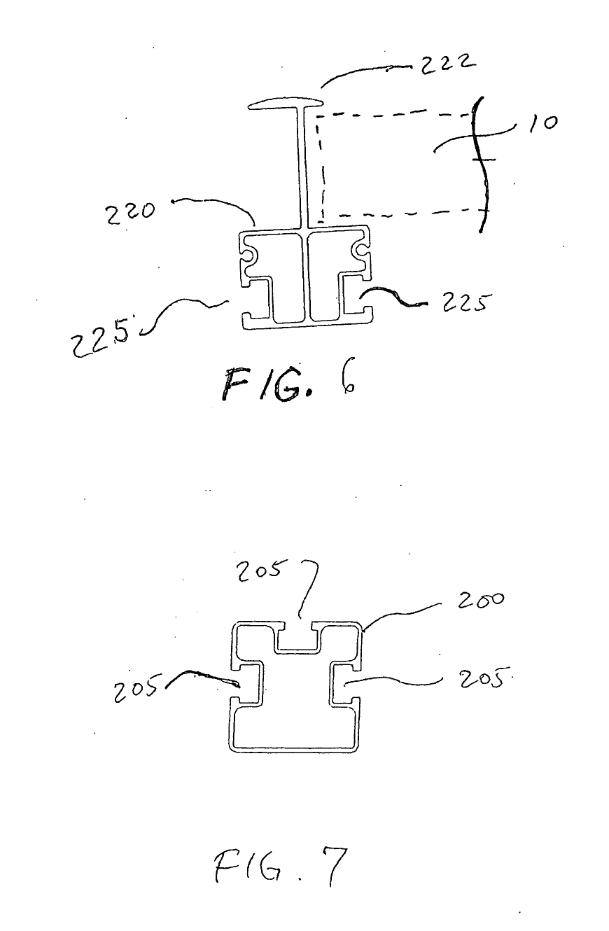

Referring now to FIG. 4, another embodiment of the present invention provides a system for installing an array of solar panels on a roof. The roof system of the present invention preferably has a vertical support member 200 and a horizontal support member 220. The vertical support member 200 is preferably mounted to the roof 15 via standoffs 232, in any conventional manner as is well known to those of skill in the art. Spacing is dictated by rafter locations and structural roof loading calculations. As seen in FIG. 5, the horizontal support member 220 is anchored to the vertical support member 200 by a clamp 230 on one or both side of the horizontal support member 220. The spacing for the horizontal support members 220 is dictated by module dimensions and a pre-determined fixed extra clearance. Once the horizontal support members are mounted, solar modules can be slipped into place. In certain preferred embodiments, better electrical conductivity for a path to ground can be ensured by installing a prickle plate washer between the components and the threaded fastener will compress the assembly together.

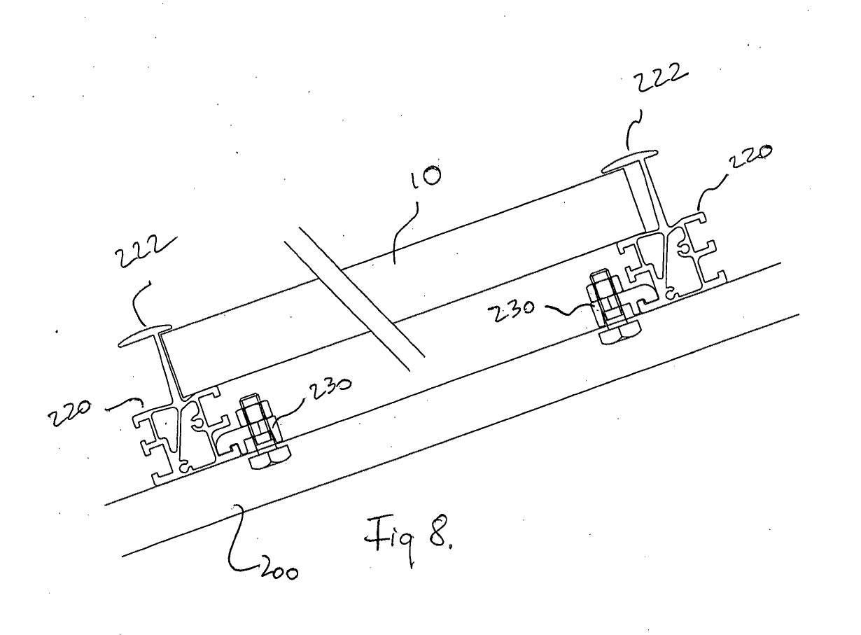

FIGS. 6-7 illustrate, respectively, elevation views of preferred embodiments of a horizontal support member 220 and a vertical support member 200 that disclose details of the cross sections of these components. Those of skill in the art will recognize that the specific cross-section of the support members 200,220 (as well as the embodiment illustrated in FIG. 3) may be modified in numerous ways and still perform the functions described herein that relate to the present invention. Additional flanges, webs, interior cavity shapes and the like are all design choices that are made based upon a variety of factors. Similarly, those of ordinary skill can readily configure the size and material of the support members. As seen in FIG. 6, the top of horizontal support member 220 has a cap 222 and a solar panel 10 can be lowered into place at an angle. The horizontal support member 220 also preferably includes one or more T-slots 225, the functions and uses of which are explained above. FIG. 7 illustrates the vertical support member 200 that lies between the roof and the solar panel array. The vertical support member 200 preferably includes one or more T-slots 205 for the reasons set forth above.

As illustrated in FIG. 8, a solar module 10 slides down into the lower portion of the horizontal extrusion 220 and become captive between the caps 222 of two parallel, facing support members 220 in the manner also seen in FIG. 4. Clearance between the module and the top horizontal extrusion 220 on the right hand side of FIG. 8 is visible. As explained below, another aspect of the present invention is methods and apparatus that compensate for this gap and ensure electrical conductivity and a path to ground for the overall array.

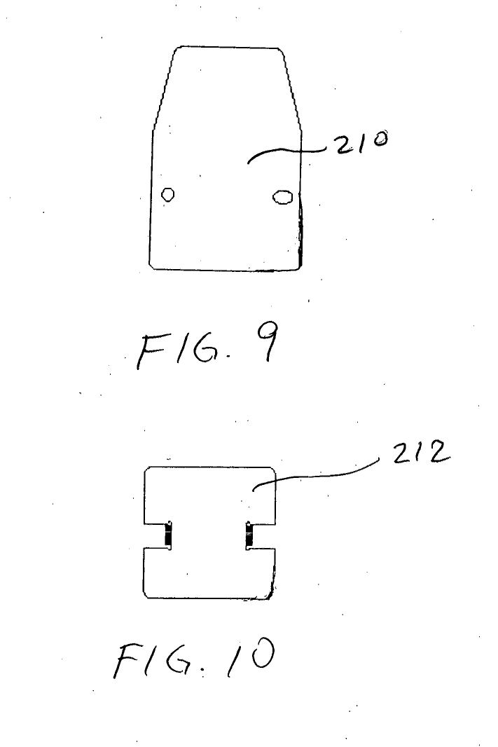

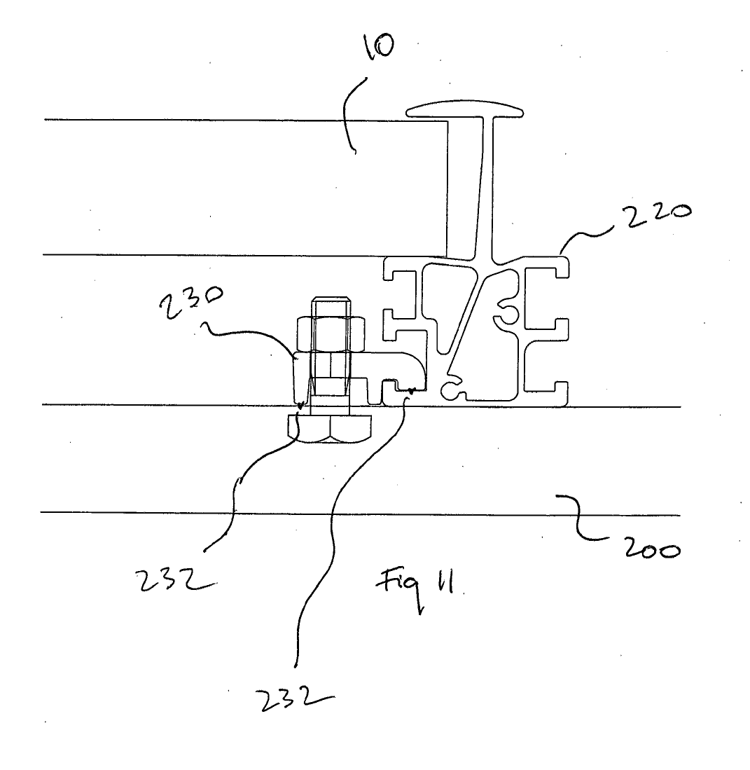

As described above with reference to the ground system embodiment, the horizontal end caps retain the array assembly in place. Vertical end caps close the ends of the vertical members for environmental and aesthetics reasons. FIG. 9 illustrates a preferred embodiment of the horizontal end cap 210 and FIG. 10 illustrates the vertical end cap 212.

In another aspect of the present invention, improved methods and apparatus for grounding solar panel arrays is illustrated. As is well known to those skilled in the art, every solar module and solar racking system must be grounded per NEC requirements. Grounding is conventionally done by installing lugs on all components and electrically connecting them together to provide a path to ground. This is time consuming, dangerous and costly, particularly on a rooftop. The system of the present invention system includes components that create an electrical path to ground during the process of assembling the support members described above and installing the solar modules, thereby making the process faster, safer and less costly.

FIG. 11 depicts the details of grounding the vertical support member 200 to the horizontal support member 220. It should be noted that as compared to the profiles of FIGS. 6-7 this embodiment (and the embodiment illustrated in FIG. 8) has four T-slots, the function of which is described herein, instead of two. The number and position of T-slots can be chosen based upon the requirements and complexity of the installation, cost and other factors familiar to those skilled in the art. In a preferred embodiment, a clamp 230, preferably made from stainless steel is installed as described above with reference to FIG. 5. The clamp 230 preferably has piercing features 232 that penetrate or “bite” into the surface of both support members (200,220) thereby creating an electrical connection between them and a path to ground. The technique of providing points of contact between support members and solar panels is generally known in the art. The present invention, however, provides a unique and integrated solution whereby the shape of the clamp 230 is specifically configured to include 232 piercing features to penetrate both vertical support member 200 and horizontal support member 220. The grounding system illustrated can also be used for installations in locations other than a roof, such as the ground installations described above, in such embodiments the vertical support member 200 would be replaced by a support structure as is known in the art.

Another aspect of the grounding systems of the present invention solves the problem of providing a conductive path between the solar modules 10 and the module support assemblies described above. During installation, it is inevitable that a gap develops between each module 10 and the adjacent horizontal support members. Those skilled in the art are aware and appreciate that various tolerances and gaps are necessary to facilitate installation, repair, retrofit and maintenance. For example, in the case of the roof system described above, a gap is typically found between the top edge of a module 100 and the top of the horizontal support member 220. On ground installations this gap develops at the side of the modules. To create a path to ground, that is, to electrically connect the frame of the module to the racking, the present invention provides a flexible electrically conductive grounding spring that fills the gap, allows for electrical connectivity and accommodates variances in the size of the gap. One additional advantage of having a flexible component is to accommodate dimensional variations due to heat expansion/contraction. Several embodiments of the grounding spring of the present invention are depicted in the drawings and described immediately below.

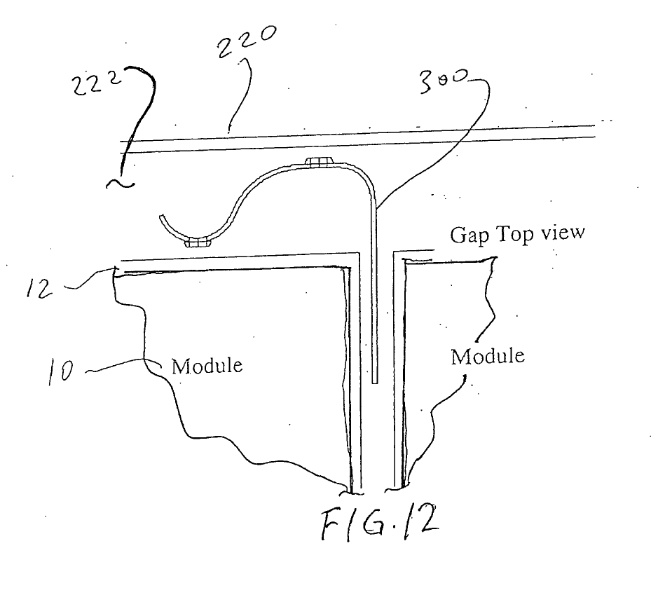

FIG. 12 illustrates a top plan view of the gap described above with reference to FIG. 8. A grounding spring 300 is installed into this gap that has two sections designed to penetrate or to “bite” into the wall 222 of the horizontal support member 220 and to the frame 12 of the module 10.

FIG. 13 is a perspective view of one preferred embodiment of the grounding spring 300 that illustrates a spring 300 formed by bending or shaping a flat piece of material, preferably stainless steel, with two sharp points 302,304. The grounding spring 300 is installed into the gap between the module and the support member in such a way that the bent end with the two sharp points 302,304 are located between the module and the support member with very little clearance when the spring is installed. The body 306 of the grounding spring 300 is twisted so that it is inserted below the module and it is captivated there by torsion. The force of the torque causes the points 302,304 to penetrate the module frame and the support member, thereby creating a path for current flow.

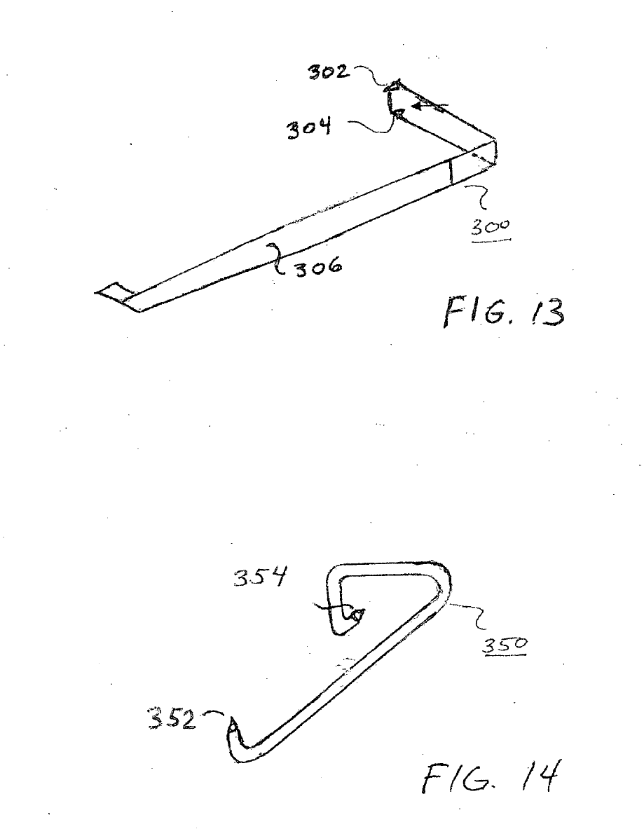

Referring now to FIG. 14, another alternate embodiment of the grounding spring is shown. In this embodiment a spring 350 is formed from wire, preferably stainless steel wire of a small diameter, circular cross section. Wire made from other materials and having other cross-sections can also be used. The wire is bent to create a sharp first end 352 that penetrates the module frame and a second sharp end 354 that penetrates the extrusion surface. The sharp ends 352,354 cut into the support member and module as described above to provide a path to ground.

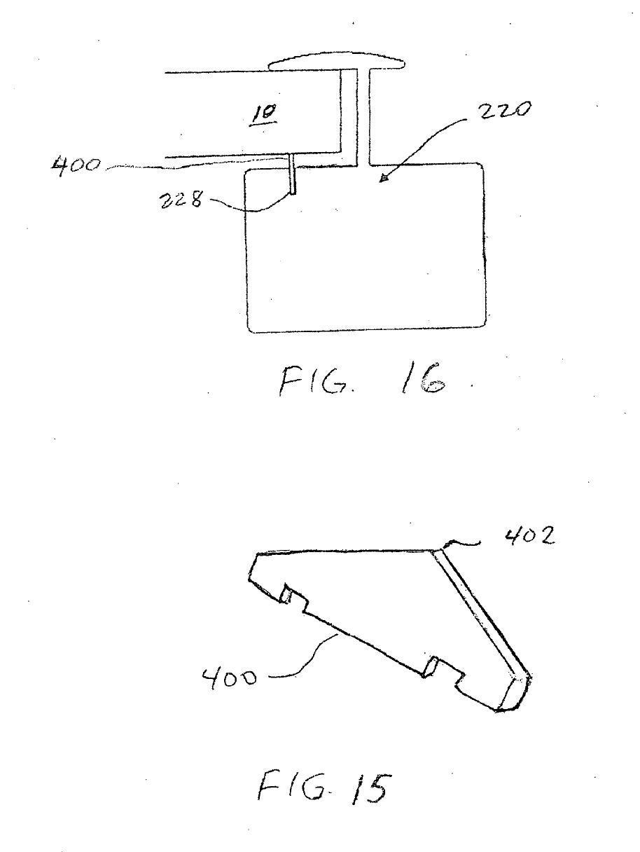

Another alternate embodiment of the grounding aspect of the present invention is the use of a wedge-like insert in lieu of a spring. As seen in FIG. 15 on embodiment of a grounding wedge 400 is preferably a triangular piece of flat, conductive material that has a contact point 402. As seen in FIG. 16, penetration of both the support member 220 and solar module 10 is achieved by placing the grounding wedge 400 within a slot 228 created in the support member 220 sized and configured for this purpose. Typically, since the support member 220 will be an extrusion member, such a slot is relatively simple to include. FIG. 16 illustrates a simplified cross-section of a support member 220 substantially the same as the support member 220 illustrated in FIG. 6 and described above, however, the grounding wedge 400 can be used with any cross section so long as the slot 228 is provided, or an equivalent in which the grounding wedge can be mounted.

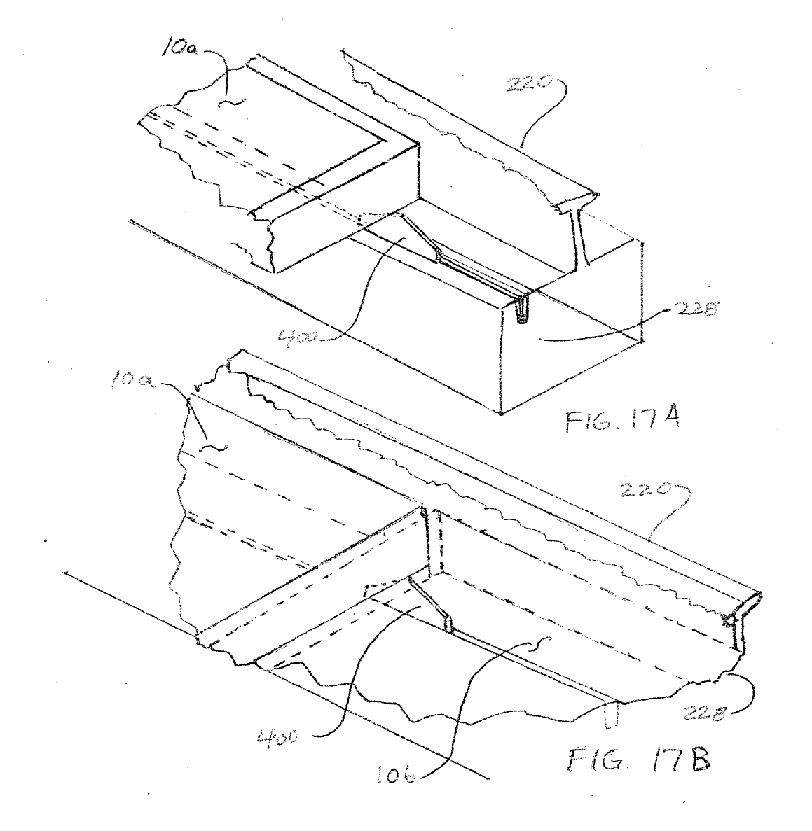

The installation of solar panels 10 using the grounding wedge 400 is shown in FIGS. 17A-17B. As seen in FIG. 17A, a first solar panel 10a is moved into place and a grounding wedge 400 installed so that the point 402 penetrates the solar panel 10a and “wedges” it into place, providing both mechanical security and electrical connectivity. Portions of the support member 220 are illustrated as having been cut away and portions of the support member and the solar panel 220 are shown in phantom. As mentioned above, for illustrative purposes the support member is shown in a simplified manner. As seen in FIG. 17B, a second solar panel 10b is subsequently slid into place to continue to complete the array, as described above and know in the art. The second solar panel 10b moves against the sloped surface of the grounding wedge 400 so that the second solar panel 10b is similarly locked in place and the assembly provides a path to ground for all the relevant structural members.

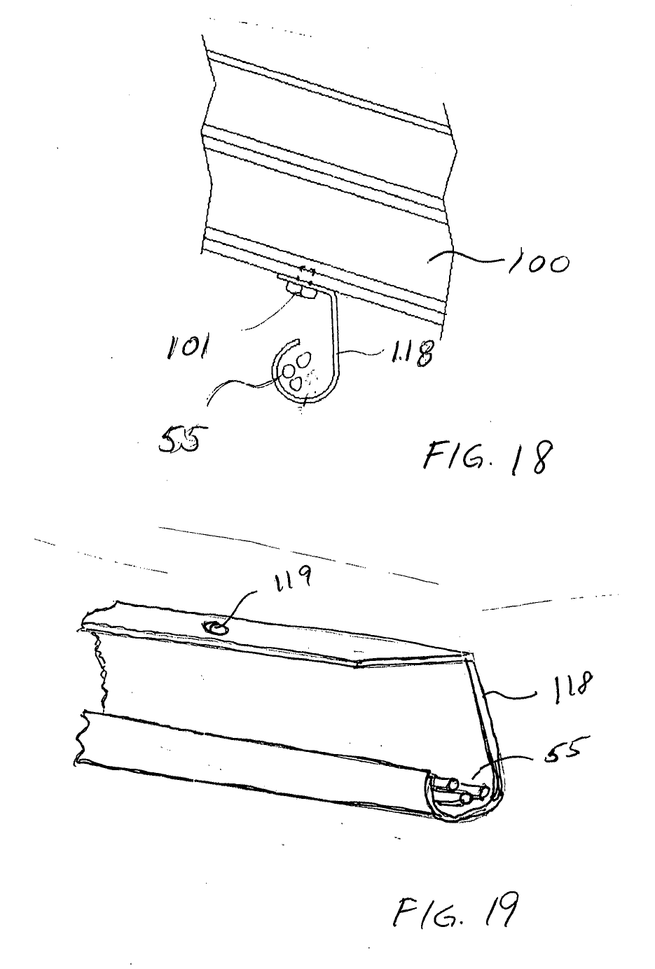

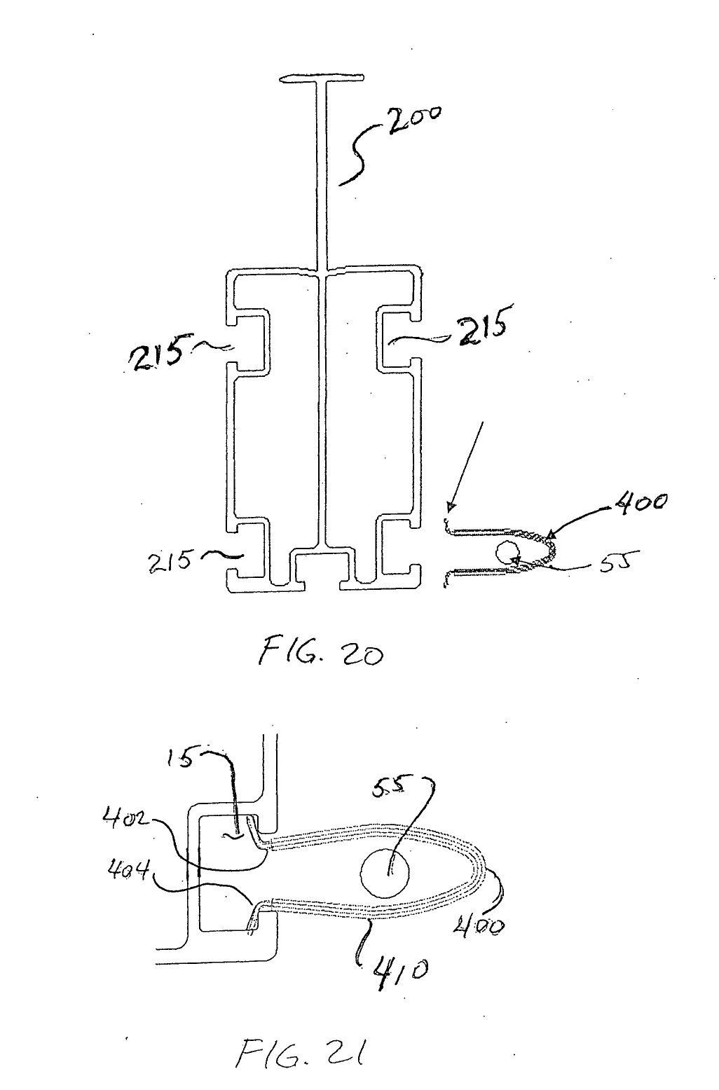

In another aspect of the present invention, improved methods and apparatus for wire management in solar panel arrays are provided. Referring now to FIG. 18 one embodiment of a wire management of the present invention is shown. A cross section of a wire management structure 118 is illustrated along with a portion of a support member 100, described above and illustrated in FIG. 3, showing how the wires 55 are run and reside within the wire management structure 118. FIG. 18 illustrates a side view of the assembly, and as seen in FIG. 19, the management structure 118 in perspective view is elongated, preferably extruded, rolled or otherwise formed so that a “tray” for holding a section of the wires 55 is created. In some embodiments, the length of the management structure 118 is long enough to span between the width of the adjacent support members, in other embodiments the length of the wire management structure 118 can be much shorter, a few inches or less. In the embodiment illustrated the wire management structure 118 is preferably installed in a ground system described above. As described above, the support member 100 preferably has T-shaped features (T-slots) 115 on both sides and on the bottom. These features allow fasteners 101 (for one example, bolts) be inserted and secured into the support member 100. In the embodiment shown, the fasteners 101 hold a wire management structure 118 to the support member 100. However, as previously discussed, the fasteners 101 may also be employed to secure the stoppers 110, or other accessories. The fasteners 101 preferably secure the wire management structure 118 to the bottom surface of the support member 100. The wires 55 are disposed and protected in a wire run within the wire management structure 118 eliminating the need for the plastic wire-ties typically used in the prior art. As known to those skilled in the art, the use of plastic wire ties is troublesome in outdoor environments because the ties have a limited life, put stress on the wire insulation at the point of contact, provide no wire protection and create an unpleasant looking installation.

The present invention also provides improved wire management apparatus adapted for the system for mounting a solar array to a roof described above with reference to FIGS. 4-10. This embodiment of the wire management system utilizes the T-slots in the support members 200,220 described above. However, it should be pointed out and understood that any extrusion, roof or ground, that has T-slots can employ this embodiment of the wire management system. Thus, although two profile shapes have been described above with reference to a preferred embodiment of a roof system, there are many more available based on the same structural feature, that is, the T-slots.

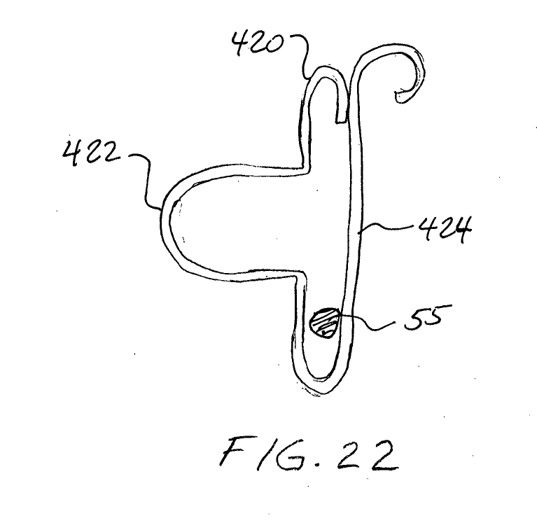

Referring now to FIG. 20, a support member 100 as described above is illustrated along with a spring clip 400. The spring clips 400 retain wire 55 and their position via spring force. Depending upon the cross-section of the clip 400, several wires 55 or a large bundle can be retained. In preferred embodiments, further wire protection is provided by a weather resistant lining 410 comprised of rubber, EPDM or the like. A preferred material for the spring clip 400 is stainless steel. Another preferred material for spring clip 400 would be weather resistant plastic. Further details are more easily described with reference to the enlarged view shown in FIG. 21. In FIG. 20, the spring clip 400 is shown before being mounted, whereas in FIG. 21 the clip is shown mounted in the T-slot 115. It will be observed that the distal ends 402,404 of the spring clip 400 have been compressed toward one another so as to squeeze the spring clip 400 and create a resistive spring force that engages the distal ends 402,404 in the T-slot 115 and retains it securely in place without requiring fasteners. As explained above with reference to the wire management structure 118, the spring clip 400 is preferably an elongated member and has a width ranging from much less than an inch to several feet, depending upon the requirements of the installation.

An alternate embodiment of a spring clip 420 is shown in FIG. 22. The bulge 422 is sized so it snaps or rotates into T-slot 115 in the manner described above. Wires are placed from the top by pulling the side leg 424 away to open access to the interior because the material is chosen for its spring properties the side leg 424 snaps shut after wire 55 is inserted.

The embodiments of the present invention are not limited to the details of construction and the arrangement of components set forth in the foregoing description or illustrated in the drawings. The present invention lends itself to numerous other embodiments, and the embodiments illustrated and described herein should not be regarded as limiting. Upon review of the description and drawings, those skilled in the art will readily devise various alterations, modifications, and improvements to the foregoing, all of which are within the scope and the spirit of the present invention. Accordingly, in order to apprehend the scope of the present invention, reference should be made to the appended claims.

What is claimed is:

1. A solar panel array system having a mounting frame substructure, and further comprising:
a support member having a cross-section, wherein the cross section comprises at least one section adapted to receive an edge of one or more solar panels and at least one T-slot.

2. The solar panel array system of claim 1, wherein the cross section comprises a lower tubular section and an upper section adapted to receive an edge, and the T-slot is disposed in the lower tubular section.

3. The solar panel array system of claim 1, further comprising at least one stopper block disposed in a T-slot.

4. The stopper block of claim 1, further comprising at least one protrusion that keys into a T-slot.

5. The solar panel array system of claim 2, wherein the lower tubular section is symmetric.

6. The solar panel array system of claim 2, wherein the upper section is extended beneath the edge, and the upper section and the edge are mechanically joined, whereby an electrical path to ground is created.

7. A solar panel array system having a mounting frame, and further comprising:
a horizontal support member having a first cross-section, wherein the horizontal cross section comprises at least one section adapted to receive an edge of one or more solar panels;
a vertical support member having a cross-section, wherein the horizontal cross section comprises at least one section adapted to receive and restrain an edge of one or more solar panels; and
a stopper block,
wherein, a clamp attaches the horizontal and vertical support members to one another to form the mounting frame.

8. The solar panel array system of claim 7 wherein at least one horizontal support member further comprises an end cap.

9. The solar panel array system of claim 7 wherein the vertical support member further comprises an end cap.

10. A solar panel array comprising a frame and one or more solar panels, wherein the frame comprises one or more support members having at least one T-slot, and a grounding system comprising at least one conductive spring disposed between a solar panel and the support member.

11. The solar panel array system of claim 10, wherein the support member has at least one T-slot, and a grounding system comprising a clamp disposed in the T-slot and the conductive spring disposed between the clamp and the support member.

12. The solar panel array system of claim 10, wherein the grounding system comprises a spring disposed between a module and a surface of the support member, wherein the spring comprises one or more penetration points.

13. The solar panel array system of claim 12, wherein the spring is formed from flat stock and the penetration points are triangular points formed on an end of the spring.

14. The solar panel array system of claim 12, wherein the spring is formed from wire stock and the penetration points are formed on an end of the spring.

15. The solar panel array system of claim 10, wherein the grounding system comprises a grounding wedge comprising at least one penetration point that is disposed in a slot in a support member and in electrical conducting contact with the surface of a module.

16. The solar panel array system of claim 15, wherein the grounding wedge is triangular.

17. A solar panel array comprising a frame made of conductive material and one or more solar panels, wherein the frame comprises one or more support members and a wire management system connected to a support member.

18. The solar panel system of claim 17, wherein the wire management system comprises a hook section for retaining one or more wires and an attachment flange comprising a connection point for mounting to the support member.

19. The solar panel system of claim 18, wherein the wire management system comprises a spring clip comprising a first section that snaps into a T-slot and a section for retaining wire.

20. The solar panel system of claim 19, wherein the first section comprises two spring legs.

21. The solar panel system of claim 19, wherein the first section comprises a curved section that snaps into the T-slot.
